(19) United States
(12) Patent Application Publication
(10) Pub. No.: US 2025/0036838 A1
(43) Pub. Date: Jan. 30, 2025

(54) COMPUTATIONAL FLUID DYNAMIC MODELING METHODS FOR UNMANNED AERIAL SYSTEMS

(71) Applicant: Purdue Research Foundation, West Lafayette, IN (US)

(72) Inventors: John H. Mott, Lafayette, IN (US); Kristoffer B. Borgen, West Lafayette, IN (US)

(21) Appl. No.: 18/781,356

(22) Filed: Jul. 23, 2024

Related U.S. Application Data
(60) Provisional application No. 63/529,040, filed on Jul. 26, 2023.

(51) Int. Cl. G06F 30/28

(52) U.S. Cl. CPC G06F 30/28

(57) ABSTRACT

Methods of generating computational models representative of bridges include receiving a first user input representative of a bridge, receiving a second user input representative of the bridge, generating a three-dimensional (3D) bridge model based upon the second user input, generating a computation fluid dynamics (CFD) model representative of an area surrounding the bridge, and performing a CFD analysis on the mesh model to generate output results. The first user input includes a bridge type selection from a plurality of stored bridge types. Each of the plurality of stored bridge types correlates to a plurality of bridge parameters. The second user input includes a plurality of bridge parameters correlating to the first user input.

### CROSS-REFERENCE TO RELATED APPLICATIONS

This application is related to and claims the priority benefit of U.S. Provisional Patent Application No. 63/529,040, entitled “Computational Fluid Dynamic Modeling Methods for Unmanned Aerial Systems,” filed Jul. 26, 2023, the contents of which are hereby incorporated by reference in their entirety into the present disclosure.

### TECHNICAL FIELD

The present application relates to computational modeling, and specifically to generating fluid dynamics models of areas around structures for use by unmanned aerial systems.

### BACKGROUND

This section introduces aspects that may help facilitate a better understanding of the disclosure. Accordingly, these statements are to be read in this light and are not to be understood as admissions about what is or is not prior art.

The Unmanned Aerial Systems (UAS) market has grown considerably over the past decade. The increase in drone use has expanded from hobbyist-seeking entertainment to a multi-billion industry with a wide range of applications, for example, medical and package deliveries, law enforcement, safety inspections, and surveying. These new applications have reduced processes historically considered labor-intensive and improved the safety of employees in several professions. Because a significant amount of capital has been invested in the UAS industry, the capabilities of UAS devices have improved, enhancing the quality, safety, efficiency, and accuracy of inspections. However, inspecting large and complex structures, such as bridges, presents unique challenges to the UAS operators relative to visibility, wireless strength, and overall safety. Therefore, efforts to enhance the functionality of UAS vehicles have accelerated.

The challenges of bridge inspections can be mitigated by using experienced UAS operators. However, the availability of pilots capable of conducting confined flights inside and around the bridge structures is limited. Training additional pilots to become skilled and comfortable with challenging conditions, such as those associated with bridge inspections, will take significant practice time. Therefore, the UAS operators may not exhibit the desired confidence required for some time due to the limited practice and training time. Converting current civil engineering bridge inspectors to a UAS pilot/inspector may enhance the quality of bridge inspections.

Increasing UAS operators' experience level will not assure that the safety of the inspections will be enhanced. However, providing the UAS pilots with advanced external tools to identify hidden hazards, such as wind turbulence and velocity, could mitigate inspection risks. Bridges are unique in their positioning, as their structures are generally located in areas where wind flows typically generate significant turbulence and wind shear around the internal bridge structure. UAS systems can withstand considerable wind gusts and velocity; however, the bridge structures may decrease the UAS vehicle's capabilities by obscuring the positioning information from the GPS navigation. Any deterioration of GPS positioning information, changing wind velocity, and wind shear locations presents unique navigation challenges in maintaining an accurate and stable UAS location.

Thus, the inventors of the present disclosure have endeavored to increase the operability of UAS systems around large structures, such as bridges, through generation of fluid dynamics models of areas around structures.

### SUMMARY

Supplying UAS operators with 3D models detailing the bridge structure and computational fluid dynamics (CFD) wind flow results may mitigate navigation risks during bridge inspections. In addition, rapid updates of the CFD model using a simplified bridge model and on-site wind conditions could allow for remote deployment of a bridge 3D model to the UAS operator.

To that end, aspects of this disclosure describe methods of generating computational models representative of structures, performing CFD analyses on the models, and providing the results to UAS for navigational use. One such method can include receiving a first user input representative of a bridge which can include a bridge type selection from a plurality of stored bridge types. Further, each of the plurality of stored bridge types can correlate to a plurality of bridge parameters. The method can further include various other acts such as receiving a second user input representative of the bridge, generating a three-dimensional (3D) bridge model based upon the second user input, generating a computation fluid dynamics (CFD) model representative of an area surrounding the bridge, and performing a CFD analysis on the mesh model to generate output results. In some embodiments, generating a computational fluid dynamics (CFD) model representative of an area surrounding the bridge can include generating a mesh model, merging the 3D bridge model with the mesh model, refining the mesh model, and defining a plurality of boundary planes of the mesh model.

This summary is provided to introduce a selection of the concepts that are described in further detail in the detailed description and drawings contained herein. This summary is not intended to identify any primary or essential features of the claimed subject matter. Some or all of the described features may be present in the corresponding independent or dependent claims, but should not be construed to be a limitation unless expressly recited in a particular claim. Each embodiment described herein does not necessarily address every object described herein, and each embodiment does not necessarily include each feature described. Other forms, embodiments, objects, advantages, benefits, features, and aspects of the present disclosure will become apparent to one of skill in the art from the detailed description and drawings contained herein. Moreover, the various apparatuses and methods described in this summary section, as well as elsewhere in this application, can be expressed as a large number of different combinations and subcombinations. All such useful, novel, and inventive combinations and subcombinations are contemplated herein, it being recognized that the explicit expression of each of these combinations is unnecessary.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

While the specification concludes with claims which particularly point out and distinctly claim this technology, it is believed this technology will be better understood from the following description of certain examples taken in conjunction with the accompanying drawings, in which like reference numerals identify the same elements and in which:

FIG. 1 depicts a schematic of one example of a bridge structure generated from user-entered variables;

FIG. 2 depicts a schematic diagram showing a hexahedral mesh generation process representative of the example bridge structure of FIG. 1;

FIG. 3 depicts a simulation output diagram of an FBX model render overview representative of the example bridge structure of FIG. 1;

FIG. 4 depicts a graphical display screenshot of an augmented reality (AR) application depiction of the CFD data for the example bridge structure of FIG. 1;

FIG. 5 depicts a simulation output diagram of an example wind shear area behind a pillar of the example bridge structure of FIG. 1;

FIG. 6 depicts a simulation output diagram of an example increase in wind velocity between bridge pillars for the example bridge structure of FIG. 1;

FIG. 7 depicts a simulation output diagram of an example side profile of the beam and bridge structure for the example bridge structure of FIG. 1;

FIG. 8 depicts a flowchart of one exemplary method of generating bridge models for use in providing fluid dynamics models of areas around the bridge structure; and

FIG. 9 depicts a flowchart of one exemplary method of providing fluid dynamics models of areas around bridge structures for use by unmanned aerial system vehicles; and

FIG. 10 depicts a schematic diagram of one exemplary system used for computational fluid dynamic modeling.

The drawings are not intended to be limiting in any way, and it is contemplated that various embodiments of the technology may be carried out in a variety of other ways, including those not necessarily depicted in the drawings. The accompanying drawings incorporated in and forming a part of the specification illustrate several aspects of the present technology, and together with the description serve to explain the principles of the technology; it being understood, however, that this technology is not limited to the precise arrangements shown, or the precise experimental arrangements used to arrive at the various graphical results shown in the drawings.

### DETAILED DESCRIPTION

The following description of certain examples of the technology should not be used to limit its scope. Other examples, features, aspects, embodiments, and advantages of the technology will become apparent to those skilled in the art from the following description, which is by way of illustration, one of the best modes contemplated for carrying out the technology. As will be realized, the technology described herein is capable of other different and obvious aspects, all without departing from the technology. Accordingly, the drawings and descriptions should be regarded as illustrative in nature and not restrictive.

It is further understood that any one or more of the teachings, expressions, embodiments, examples, etc. described herein may be combined with any one or more of the other teachings, expressions, embodiments, examples, etc. that are described herein. The following-described teachings, expressions, embodiments, examples, etc. should therefore not be viewed in isolation relative to each other. Various suitable ways in which the teachings herein may be combined will be readily apparent to those of ordinary skill in the art in view of the teachings herein. Such modifications and variations are intended to be included within the scope of the claims.

Reference systems that may be used herein can refer generally to various directions (for example, upper, lower, forward and rearward), which are merely offered to assist the reader in understanding the various embodiments of the disclosure and are not to be interpreted as limiting. Other reference systems may be used to describe various embodiments, such as those where directions are referenced to the portions of the device, for example, toward or away from a particular element, or in relations to the structure generally (for example, inwardly or outwardly).

### I. Overview

The potential applications of Unmanned Aerial Systems (UAS) have grown significantly over the past decade. One of the new applications of UAS is to conduct safety inspections of bridges. Bridge inspections are an expensive and time-consuming process that varies significantly with the bridge's style, height, width, and length. Inspections create interruptions that interfere with bridge usage, as inspections typically require partial or total closure, causing interruptions and traffic delays. The change in traffic patterns at or near the bridge also increases the likelihood of traffic accidents and injuries. A UAS can fly into confined areas and visually conduct a detailed, high-quality survey of the bridge structure; however, UAS performance may be impacted by the lack of positioning signals (GPS), high wind velocity, and wind shear. UAS operators with significant experience in conducting bridge inspections are capable of safely navigating the vehicle inside and around bridge structures. However, with a shortage of experienced UAS operators, it is critical to train and develop UAS pilots to use tools and technology capable of visualizing and managing the bridge structure's hazards. Given the essential structural characteristics of a bridge, a computational fluid dynamics (CFD) application can be utilized to estimate the current wind conditions. The CFD result can be used by an augmented reality tool allowing the UAS operator to visualize wind flows inside and around the bridge.

Bridge inspections follow complex procedures and require teams with specialized skills to be dedicated to conducting them. The inspection teams perform various tasks ranging from measurement and evaluation of the bridge structure by structural engineers to traffic management studies of pedestrians and vehicles. Bridge inspections typically require closing the structure to most or all forms of traffic, creating interruptions and delays on the bridge and in the area below and near the bridge, thereby increasing the risk of traffic incidents and injuries to the inspection workers. Therefore, limiting the period of time a bridge is restricted is critical to safety. The closure duration depends on the bridge's location, type, and age. Most bridge inspections require a combination of skilled crews, some of whom physically climb the concrete and metal pillars, and others who operate telescopic trucks with bucket lifts to physically inspect the portion of the bridge above and below the deck. The inspection procedures require documentation of a visual inspection on all surfaces of a structural member, including internal edges and faces. The inspection procedures are similar to those for other large structures, such as cellular towers and elevated water tanks, which also require crews to scale the structures. However, these other structures are typically located in remote areas where managing traffic flows and bystanders is less necessary.

The visual capabilities of UAS have increased significantly as camera technology has improved the resolution capacity of imaging sensors. The improved quality of cameras has led to increased use of photogrammetry methods that create accurate high-resolution models from photos. Photogrammetry creates models with accuracy comparable to LIDAR-based sensors and visual inspections. Creating the photogrammetry models requires precise control of camera parameters such as the focus, the white balance, and the aperture. In addition to cameras, multiple advanced sensor types are now available on UAS platforms, such as infrared thermal imaging, LIDAR, and multispectral. The benefit of additional sensor types is their capability to reveal subsurface cracks by comparing the thermals of the concrete and steel members in the search process.

A certification is required to operate a UAS in the United States National Airspace System, and the ability to perform inspections is subject to Federal Aviation Administration's (FAA) regulations (Part 107). FAA regulations outline the procedures for UAS operations around buildings, people, and airspace. The operation of UAS vehicles can be intimidating and complex, and for individuals with limited flight experience, the complexity of the operation can be daunting without the supervision of an experienced UAS pilot. UAS operators typically practice and train using UAS in open scenarios; transitioning to UAS operations at or near large structures increases the complexity and risks. The additional perils include the vehicle's proximity to the structure, the activities above and below the individuals or vehicles, and the external factors affecting the performance of the UAS. The pressure and stress around inspections can be mitigated through increased training, the use of supplemental flight tools, and simulated operations in a controlled environment. The use of mock structures and set-up procedures as part of the training and certification can establish enhanced guidelines and capabilities for UAS operators.

### II. Challenges

UAS operations near and around large civil structures may be affected significantly by challenges such as GPS denial of service, wind shear, and ground effect. Experienced pilots are familiar with such hazardous elements and can navigate to avoid them more effectively than inexperienced pilots. Due to the GPS navigation system's importance, denial of GPS signals is a primary concern for UAS operators. The large concrete and steel structures commonly found in bridges, water towers, and cellular towers can cause interruptions in the GPS navigation signal. A lost GPS signal can cause issues in the navigation systems due to the reliance on GPS as the primary navigation method. Typical UAS flight systems are capable of mitigating brief, temporary GPS outages. However, an extended period of obstructed GPS signals will cause location accuracy to decline. A typical backup guidance system for GPS signals is an Inertial Measurement Unit (IMU); however, the degree of electromagnetic interference and vibration on a UAS can create anomalies in the vehicle that accumulate into significant position shifts.

Operations inside and around bridge structures will exacerbate the probability and length of GPS denial. These periods further deteriorate the capability of the UAS to maintain precise locations due to the forces created by the wind, turbulence, and ceiling effect. Wind compensation capabilities of UAS platforms vary depending on the physical characteristics of the vehicle and compensation algorithm. Multiple UAS platforms can withstand substantial wind velocities, often up to 20 knots. Wind compensation quality depends on the steady-state and intensity of the wind gusts. When the vehicle relies solely on the IMU during periods of obstructed GPS signals, the wind correction capabilities decrease.

Wind flowing through the bridge structures can accelerate and produce shear and turbulence. Wind shear and turbulent areas are a significant concern due to the wind velocity differences and unpredictability. Multirotor UAS vehicles have unique operating characteristics when operating near flat surfaces. The high-speed rotors create a vacuum around the blade tips and directly above the propeller, causing a strong suction force towards the structure. This phenomenon, known as ground effect, causes a low-pressure area limiting the distance the vehicle can operate from flat bridge surfaces. Therefore, operations inside bridge structures with multiple flat surfaces can cause issues, forcing the UAS to operate safely away from the structure. Current mitigation procedures focus on mechanical solutions such as cages to prevent damage to the rotors. Newer flight vehicles may contain onboard sensors that prevent the vehicle from creating the ground effect.

### III. Data Collection Instruments and Processing

Wind heading and velocity, latitude, longitude, altitude, and the timestamp of all wind headings and velocities can be collected. In one experimental example, a stationary ground-truth and a mobile drone-mounted anemometer recorded all the required data parameters. The ground truth and the drone-mounted instruments may contain a sonic anemometer and a GPS receiver. Wind heading and velocity can be collected using Sonic anemometers, while the GPS receiver and flight vehicle provide the remaining time stamp and location data points. The wind heading and velocity from nearby weather stations can also be collected as an additional reference for the current wind conditions.

Sonic anemometers use ultrasonic transducers to calculate the wind speed and heading across two or three dimensions depending on the configuration. Two sonic anemometers can be utilized to record the wind heading and velocity, whereas one may be mounted to a drone as it is flown around the bridge and one may be stationary on the ground near the bridge structure. The stationary anemometer is treated as a ground truth station and placed in an open area near the bridge. The data collected is used as a reference for the wind conditions during the flight. Each sonic anemometer can independently record data in each axis, representing U, V, and W. The drone-mounted anemometer can have unrestricted measurements for all three axes, whereas the ground truth station is restricted vertically.

Accordingly, the wind data may be measured independently on each axis, and the current rotation of the anemometer is logged. The next step of the process is to remove errors induced by the movement of the flight vehicle. The primary data elements removed are the wind velocity induced by the flight vehicle and the angle of the flight vehicle. The flight vehicle records its velocity on each axis and as a total sum of the horizontal velocity. As a total sum of the vectors, the total horizontal velocity is used for offsetting due to the flight vehicle being flown in two headings during the entire flight. The vehicle's yaw determines the offset, and the current velocity is offset to the sonic based on the rotation. Next, the induced velocity from the drone correcting the pitch angle is removed from the velocity. The angle of the drone combined with the lever arm and the time elapsed is used to estimate the velocity removed from the readings. Once the errors from the drone movement have been removed, the next step of combining vectors is performed.

There are three initial CFD conditions, which come from two sources. One of the sources is the ground truth station, and the other is the a nearby station, such as a local airport. The mean and gust values from each source may be used for the CFD setup when available. Before the UAS flight, ground truth may be set up to record wind values. These values before takeoff are the initialization values. The mean is the total sum from the sensor startup to the start-off take-off. The gust value from the ground truth is the three-second rolling average from all values, with the highest value used as the gust initialization.

### IV. Generation of CFD and Bridge Models

Computational fluid dynamics (CFD) models allow the user to mathematically process fluid flow through an area around objects. Applying the same concept to airflow around civil structures can allow the CFD model to predict wind flows. For example, a UAS operator can interpret the CFD model results to establish safe operating areas during a bridge inspection.

The CFD process begins with a computer-generated model of the bridge structure, which may be generated using a plurality of user inputs. Multiple file types and models are supported for CFD processing; however, increasing the model's complexity increases the processing requirements. Therefore, 3D models suitable for CFD simulations may not be readily available for existing bridge structures. Bridges are complex structures with thousands of parts, and the number and complexity of the parts will vary based on the bridge's dimensions, age, and style. The use of 3D models which contain every element and detail of the bridge will dramatically increase the processing time for the CFD software. Simplifying the model to include only the primary components that affect the UAS will decrease the computing constraints while maintaining a reasonable 3D file size. The simplified model can provide adequate wind characteristics for UAS operations without requiring every bridge component.

The bridge model generation process may be completed using one of several systems and methods. Two such methods are described herein: Computer-Aided Design (CAD) and Photogrammetry. The CAD option for the bridge generation process is to create the model parametrically using software packages such as Fusion360, CATIAV5, or FreeCAD. The primary bridge data storage is located within the structure's BIM system. It can be used with online repositories such as Google Earth, HistoricBridges.org, and BridgeHunter.com, which provide public access to engineering drawings. These sources provide public structural information; however, the various DOTs and private engineering firms have repositories of drawings and CAD models for the bridges. Existing information, such as drawings and CAD models from other sources, can be transferred by taking the dimensions from the documentation or directly exporting them into a file type supported by the CFD software. The structural data from drawings or unsupported file formats is used to generate a one-off CAD model or automatically generated through a Python script. The Python script is selected from the bridge type: pony truss, girder, beam-girder, truss. After bridge style selection, the script prompts the user to input the desired variables. The variables required depend on the bridge type.

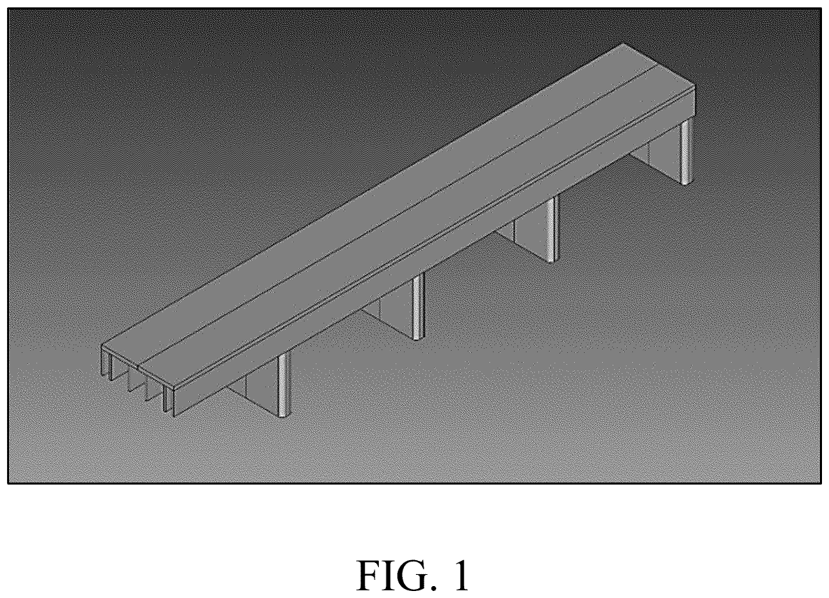

One example bridge selected for analysis is a concrete and steel beam walking bridge crossing the Wabash River in Lafayette, Indiana. The bridge is located between two automotive bridges to the north and south. Both were excluded from the CFD calculation to reduce model complexity and limit the focus to the walking bridge. Bridge dimensions were collected using publicly available data and measured as necessary. The parameters and values used to replicate the walking bridge are shown in Table 1 below. The generated CAD model from the beam bridge Python script using the user-entered variables is shown in FIG. 1.

TABLE 1
List of dimension parameters used for the bridge CAD model

| Parameter | Dimensions (mm) |
|---|---|
| Pillar width | 3,000 |
| Pillar height | 15,000 |
| Beam thickness | 500 |
| Beam height | 6,000 |
| Beam length | 140,000 |
| Beams gap | 5,000 |
| Number of beams | 6 |
| Road deck thickness | 1,000 |
| Support pillars | 4 |
| Pillar spacing | 108,000 |
| Fillet | 1,000 |

Photogrammetry may also be utilized for creating a bridge model for CFD software. This technique was previously applied in CFD applications, particularly high-resolution topographic maps, to analyze wind effects based on terrain features. Recent studies have extended its application to capturing sail geometries and using the resulting models to simulate wind flows in CFD analyses.

Three different photogrammetry software packages were evaluated to determine the best package. Each software package was evaluated based on dimensional accuracy, details, and voids in the mesh. All the packages were given the same image datasets, which were collected using Skydio's 3D scan feature. Pix4D, MeshRoom, and MetaShape are the three photogrammetry software packages that generate the bridge models. Each model was evaluated visually to determine the best model generation software. The mesh quality was found to be dependent on the photogrammetry software used. MeshRoom was missing details on multiple structure areas compared to Pix4D and MeshRoom. Pix4D's overall quality was lower than MetaShape. MetaShape was selected as it resulted in the best-quality output for the same photo dataset. All three photogrammetry packages required repairs to the mesh before running the CFD simulations. All the meshes were of all quality and were conducted using a visual evaluation of the model. The two primary errors in the photogrammetry model are the voids present in the mesh and the missing members. The resolution and detail of the model are less of a concern for the CFD modeling due to the process that generates the internal computational mesh for the CFD. This process reduces the quality and size of the object to the determined mesh size, which is a function of the computational width and the number of cells on each axis.

Another benefit of the photogrammetry generation process is that the generated model can be overlaid on the CAD as a validation step. This step allows for an additional comparison to ensure that the correct dimensions were used for the CAD model and that no significant holes remain in the photogrammetry model. After processing in the CFD, there were no significant deviations in velocity from either model.

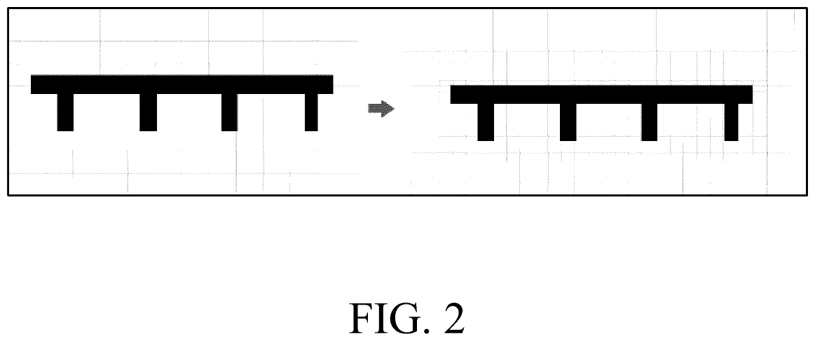

The CFD software selected is the Open-Source Field Operation And Manipulation (OpenFoam) numerical solver. OpenFoam contains multiple utilities and solvers designed to initialize and complete a CFD model calculation. The computational domain is a hexahedral mesh generated using the OpenFoam utilities blockMesh and snappyHexMesh. The utilities were selected for their parameter-controlled properties, case of modification, speed, and efficiency during mesh generation. The density of mesh vertices and the number of vertices affects simulation performance and calculation time. Closer points yield more accurate results; however, closer spacing increases computing time. The spacing between the vertices is controlled by mesh generation and refinement parameters within blockMesh and snappyHexMesh. The vertex spacing was selected where any Da-Jiang Innovations (DJI) UAS would cover at least two vertices in each dimension. The UAS model selected for inspections was the Mavic 2 Pro, with a measured width of 66 cm (26 in). A minimum spacing of 50 cm was chosen to provide a margin in the mesh generation. The computational mesh is initialized as an empty three-dimensional hexahedral grid by the blockMesh utility. The bridge object generated by the Python script is merged with the blank grid mesh using snappyHexMesh. The mesh is then refined around the bridge surfaces until the 50 cm spacing value has been reached; the snappyHexMesh process is illustrated in FIG. 2. The completed mesh resulted in 185,237 cells sharing 218,801 unique vertices.

The final step for the mesh is to define the boundary planes required for the transitions between the internal and external computational domains. The wind origin, exit, and transfer planes are established using symmetry, ground, inlet, and outlet planes. Two types of transfer planes are used in the model, symmetry and ground planes. Symmetry planes represent free-flowing wind in the environment outside the computational domain, while ground planes represent the boundary layer created by terrain. Three symmetry planes are used in the model to control the ceiling, left, and right mesh limits. The river flow was defined as a non-moving ground plane to reduce the simulation complexity of running water. The ground plane was set to four feet above the lowest points of the pillars as the water level will typically vary from two to eight feet during the year. The inlet and outlet planes represent the origin and departure of wind flow from the internal mesh. The inlet establishes the ten m/s wind conditions perpendicular to the bridge span, and the outlet maintains the pressure created by the inlet flow.

The completed mesh can be solved through multiple turbulent flow models, each with various benefits and drawbacks. Three models commonly used in practice to solve simulations with a high Reynolds number are Reynolds-Averaged Navier-Stokes (RANS), Direct Numerical Solution (DNS), and Large Eddy Simulation (LES). The RANS method was selected as it has the shortest average computational time; however, the accuracy and resolution of turbulent flow is decreased due to the solutions averaging process. The process used for solving the RANS equations is the Semi-Implicit Method for Pressure Linked Equations (simpleFoam) solver native to OpenFoam. SimpleFoam is a guess-and-correct process for the Reynolds Averaged Navier-Stokes (RANS) method of estimating wind velocities across large structures containing turbulent airflow. The turbulence model selected for the RANS solver is the Shear Stress Transport (SST) k-w due to the advantages in boundary layers, the transmission of turbulent stress, and fluid separation. For incompressible Newtonian flow, the velocity and pressure equations of the Reynolds-Averaged momentum equations are shown below in Equation 1.

$$ρ \frac{\partial {u}_{i}}{\partial t} + ρ \frac{\partial }{\partial {x}_{j}} ( {u}_{i} {u}_{j} ) = - \frac{\partial p}{\partial {x}_{j}} + v \frac{\partial }{\partial {x}_{j}} ( \frac{\partial {u}_{i}}{\partial {x}_{j}} ) , \frac{\partial {u}_{i}}{\partial {x}_{i}} = 0 , \qquad ( “ Equation 1 ” ) .$$

Where uᵢ or uⱼ is the velocity component in the x, y, or z direction, ρ is the density of the fluid, and v is the kinematic coefficient of the viscosity. The Reynolds-Averaged equations are solved by using the sum and current state mean with u representing the velocity and p as pressure, shown in Equation 2.

$$\begin{matrix}u ( x , t ) = \overline{u} ( x ) + {u}^{′} ( x , t ) , & p ( x , t ) = \overline{p} ( x ) + {p}^{′} ( x , t ) ,\end{matrix} \qquad ( “ Equation 2 ” ) .$$

Substitution of the Reynolds-Averaged equation in Equation 2 above with the incompressible Newtonian flow equations from equation 1 yields the Reynolds Averaged Navier-Stokes (RANS) equations as shown below in Equation 3, where Sᵢⱼ represents the mean rate of the strain tensor.

$$ρ \frac{\partial \overline{{u}_{ι}}}{\partial t} + ρ \frac{\partial }{\partial {x}_{j}} ( \overline{{u}_{ι} {u}_{J}} ) = - \frac{\partial \overline{p}}{\partial {x}_{j}} + v \overline{{u}_{ι}} + \frac{\partial {S}_{i j}}{\partial {x}_{j}} , \frac{\partial \overline{{u}_{ι}}}{\partial {x}_{i}} = 0 , \qquad ( “ Equation 3 ” ) .$$

A drawback to RANS is the potential of the calculation to reach an unstable state. However, the instability can be eliminated by using relaxation factors. The high Reynolds number solution's relaxation factors were 0.3 for pressure, 0.7 for velocity, and 1×10⁻⁴ residual convergence. Four hundred iterations were calculated, with the final time step result exported to the UAS operator. The average computation time for the CFD calculations and model generation for five runs was six minutes.

The results from the CFD computation are converted into an Autodesk Kaydara FilmBox Digital Content file (FBX). FBX is a standard format for interoperability between digital content creation software for a three-dimensional design capable of being viewed on multiple software packages. The file is generated by a Python script that parses the results database, converting the cell location and velocity information into an FBX model. While the file can be viewed in any format that supports it, a custom application is required to manage the multiple objects in the file correctly. The development of the application was created with Unity Game Engine. Unity contains development utilities and tools capable of deploying the same software package to multiple platforms such as Android, iOS, and Windows.

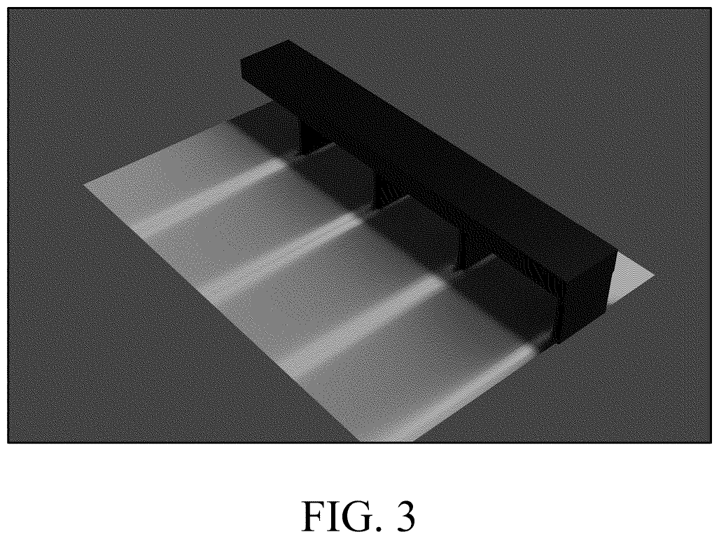

The FBX file consists of the generated bridge model and multiple wind layers. Each wind velocity layer may be displayed, via the user display, as a two-dimensional layer plane around the three-dimensional bridge model. Every layer is spaced equidistantly at 50 cm to maintain adequate vertex coverage for the flight vehicle. The layers are generated by inserting a plane in the computational mesh at the location of the selected velocity layer. The intersection of the plane and the cell faces results in a line. The midpoints of all the intersections are then added to the velocity layer, with nearby points combined into triangle faces. Every vertex retains pressure and velocity information from the original cell, and the vertices display the velocity as a color grade. All layers are independent within the FBX format allowing for manipulation of the sub-objects within the file, color data, and interoperability between platforms. A screenshot of the model with the one-meter layer slice visible and the bridge model overlaid is shown in FIG. 3.

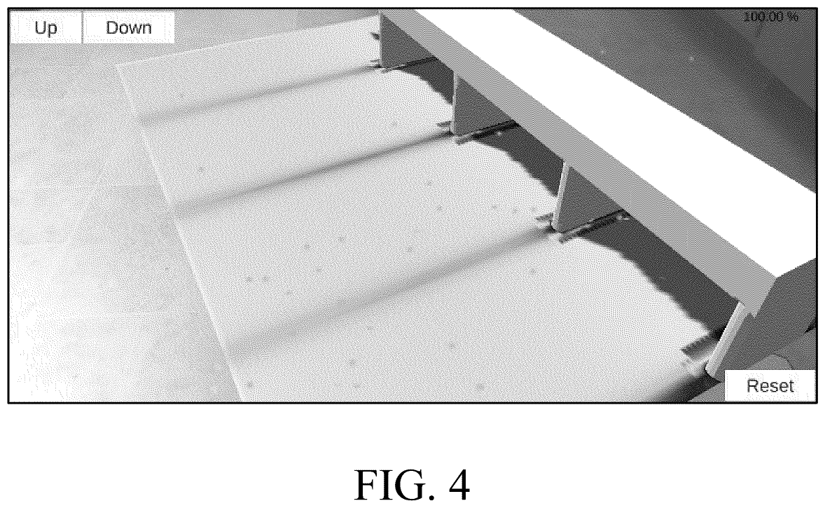

The interoperability of the file format allows use on any computer or smartphone. The software version for the laptop uses a traditional navigation experience similar to those associated with CAD packages. The smartphone application will rely on augmented reality for viewing and navigation, enabling the UAS operator to physically navigate the model in three dimensions. In addition, the interactions with augmented reality increase the UAS operators' awareness of hazards and safe locations to fly the UAS. The phone application uses Google's ARCore or Apple's ARKit to provide the framework for deployment dependent on the operating system of the phone. The CFD model from the example bridge in Lafayette contained 120 velocity layer objects for a total size of 15.4 MB. Cycling through the layers is accomplished with buttons to shift between the layers and a toggle button to alternate between side and top views. A screenshot of the augmented reality application on a Samsung S9 is shown in FIG. 4.

The results of the analysis are discussed in terms of the impact of conducting the bridge inspection for the UAS operator. The UAS pilot can select the wind velocity layer closest to the current altitude or position of the UAS to view the corresponding wind information. The colors represent the velocity of the wind flow using the Jet color scheme (red is high velocity and blue is low velocity). The velocity is displayed as total magnitude relative to the initial condition of ten m/s perpendicular to the bridge span. The results of the CFD simulation resulted in a wind velocity increase and decrease to 17.4 m/s and 0.4 m/s respectively. UAS operators can then identify hazardous locations created by the wind shear and high-speed airflow.

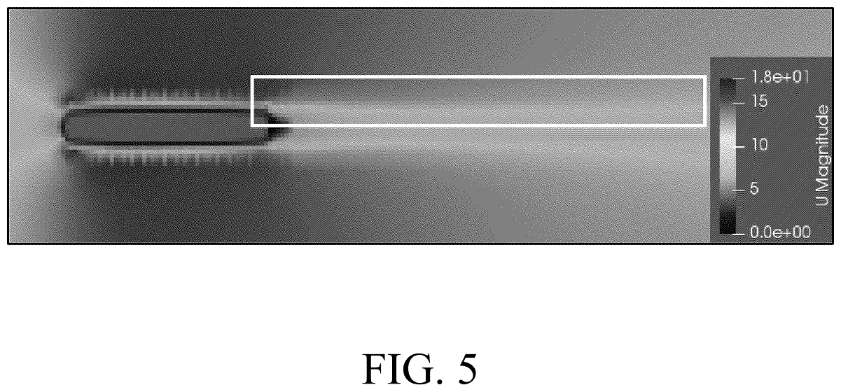

Wind shear is a hazard to UAS operators as the asymmetric thrust applied to the vehicle increases the difficulty of maintaining position and producing a stable image. An example of wind shear from the CFD model is displayed within the white box in FIG. 5. The severity of the shear line decreases as the flow moves leeward from the pillar.

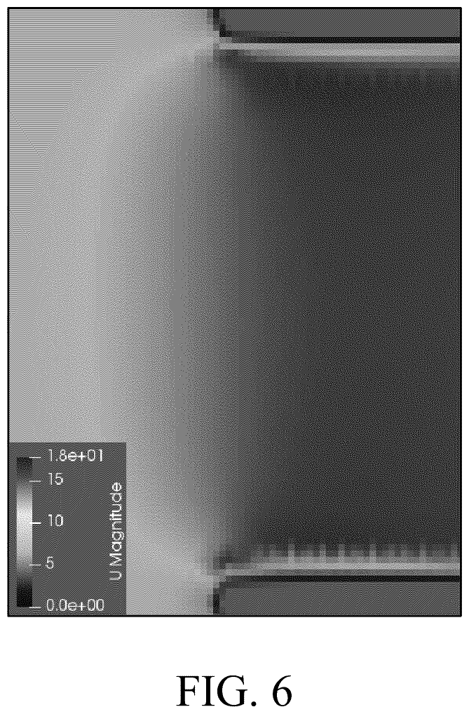

Another concern during UAS operations is the generation of high-velocity wind around bridge components. The stronger velocity wind flows cause the vehicle to increase the current draw on the battery, decreasing the UAS performance. Therefore, minimizing the duration the vehicle spends in the high-velocity wind flows will improve the efficiency of the flight. Dark red colored regions identify the high-velocity wind flows in the figures. The increased velocity above the bridge reduces the correction capabilities of the UAS location during GPS conditions. FIG. 6 shows the high-velocity area between the bridge pillars, where the velocity increases to 14 m/s from the starting ten m/s. The increase in velocity is caused by the venturi effect of the pillars and beams.

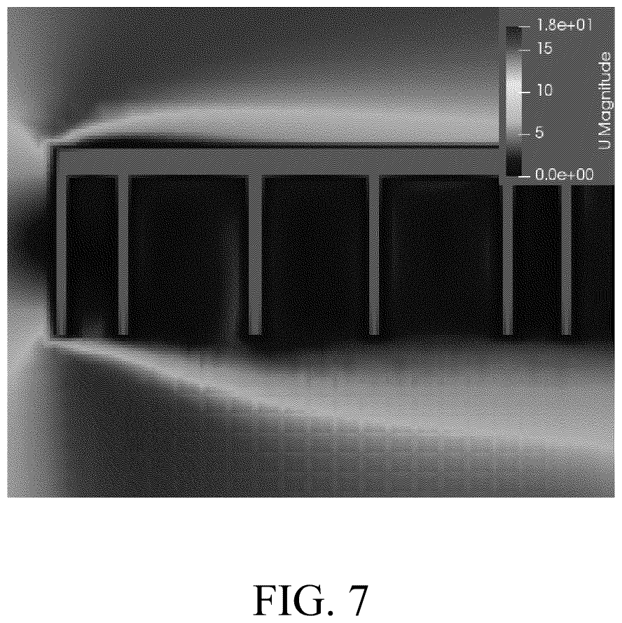

Multiple viewing perspectives of the velocity slices improves the operator's awareness of wind hazards. The side-view shown in FIG. 7 displays additional wind shear and high-velocity areas that were not apparent in the top view. Similar to the wind shear around the pillar, the severity increases as the UAS moves windward until past the bridge. The profile of the steel beams creates multiple low-velocity pockets across the length of the span.

Accordingly, the process presented within this document is a software tool for UAS pilots that can aid in wind hazard identification. Managing the wind conditions is critical for the UAS operator to maintain inspection quality, safety, and efficiency. Successful inspections require the UAS to traverse wind shear lines and maintain position in high-velocity flows. Therefore, preparing the UAS operator for wind hazards can mitigate the risks of a bridge inspection. The process includes constructing bridge models and using computational fluid dynamics simulations to solve them and allowing individuals to generate results. In some instances, the generated results may be transmitted to a UAS in real-time or near real-time to aid in the operation of the UAS during flight.

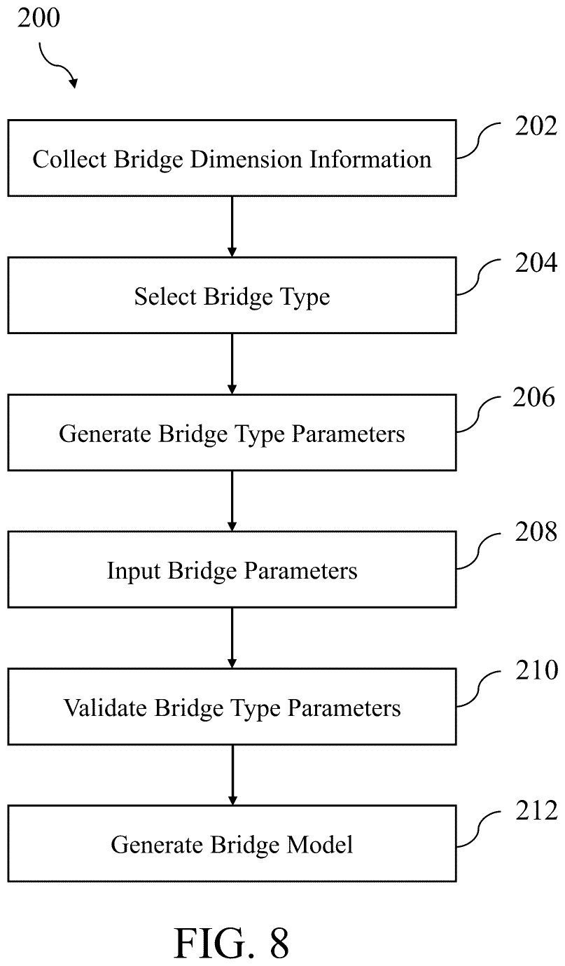

FIG. 8 shows a flowchart representation of one method (200) of generating a model of a bridge structure for use within a CFD analysis. At step (202), bridge dimension information is collected which is representative of a real bridge to be modeled. The bridge dimension information may be collected in any of a variety of ways, such as through field measurements, satellite imagery, existing blueprints, existing CAD files, or any other way to collect information of the bridge. At step (204), a user selects a bridge type from a repository of stored bridge types which are each representative of a common bridge configuration. For example, seven or more common bridge types may be stored within a memory system for selecting. Thereafter, at step (206), the system (e.g., the processor) may be configured to generate a listing of bridge parameters associated with the selected bridge type. The parameters may also be stored in the memory and correlated with the bridge type. For example, the system may store combinations of formulas, scripts, and variables to generate a bridge of the selected bridge type by using the inputs such as length, width, height, offset, etc. Next, at step (208), the system may prompt the user to associate the bridge information collected at step (202) with the listing of bridge parameters from step (206). At step (210), the system may initiate a review of the inputs to ensure the inputs are each within valid ranges. Further, the inputs may be provided by the user via a batch file (e.g., a comma separated value file or Microsoft Excel file). Finally, at step (212), a bridge model is generated. In some embodiments, the bridge model is a simplified version of the real bridge with few rivets, details, or other features which would have little to no impact on the CFD results. By generating a simplified model, less data and computing power is required to analyze the model and transfer the data. However, it should be understood that a more complex model may be generated if such an application requires it.

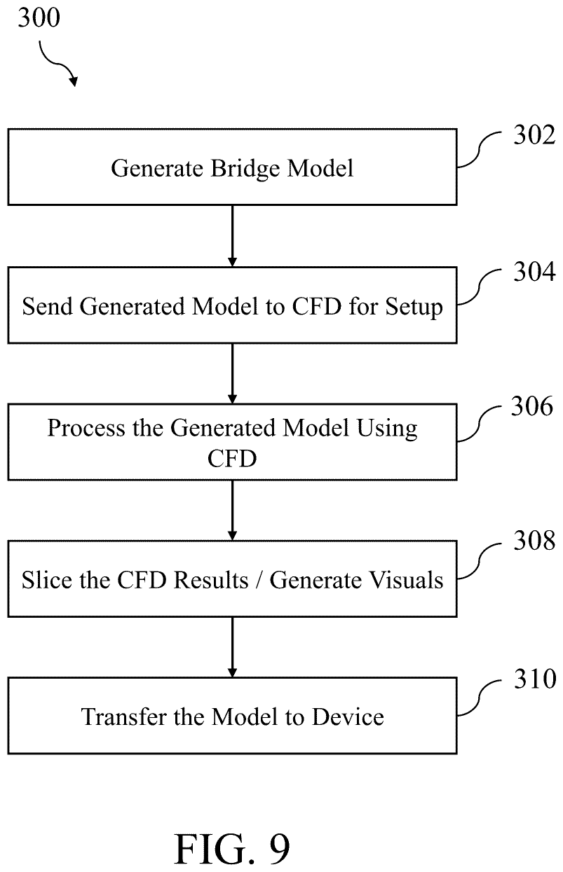

FIG. 9 shows a flowchart representation of one method (300) of providing fluid dynamics models of areas around structures for navigational use by unmanned aerial system vehicles. While bridge structures are described herein below with regard to method (300), it should be understood that various other structures may be similarly modeled and considered during navigation using the methods described. At step (302), a structure model (e.g., bridge model) is generated. This model may be generated using one of a variety of methods, such as method (200) described above. At step (304), the model is input into a software system configured for CFD analysis. In some embodiments, a script (e.g., a python script) may be used to transfer data from the model to the CFD environment. At step (306), the model is processed using CFD. One example of a CFD solver is the SimpleFOAM (RANS) solver provided by The OpenFOAM Foundation Ltd of London, England. At step (308), the CFD results from step (306) are post-processed to generate visual results. In one example, the CFD results are sliced in a post-processing software such as Para View provided by Kitware, Inc. of Clifton Park, New York. Finally, at step (310) the visual model is transferred to a device, such as an unmanned aerial vehicle, for navigational use. In some embodiments, the visual model is updated at regular intervals, or in near-real time, to provide the model to the device. In some embodiments, the model (with or without wind data) is provided to a display device of a user.

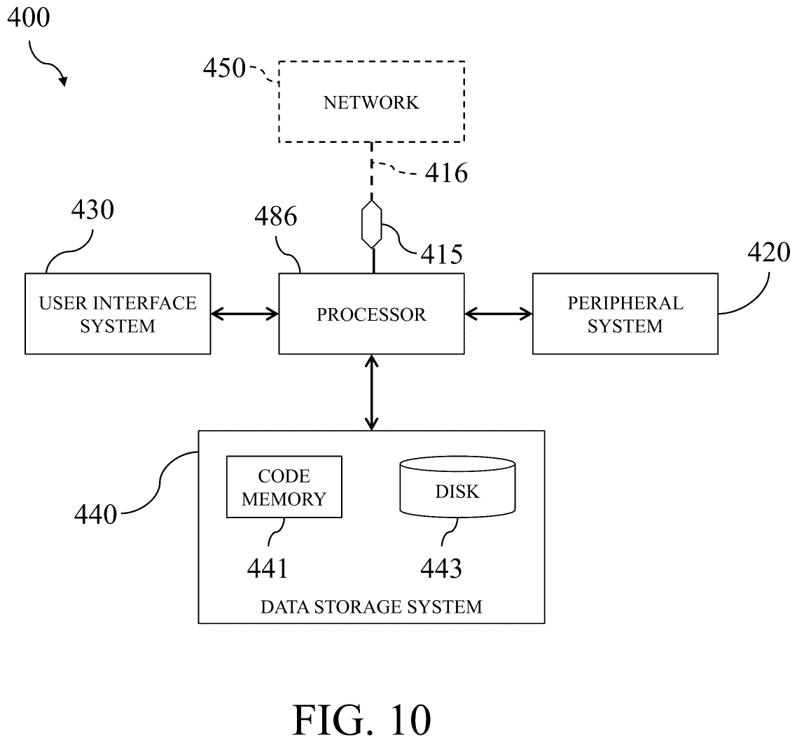

FIG. 10 is a high-level diagram showing the components of an exemplary data-processing system (400) for analyzing data and performing other analyses described herein, and related components. The system includes a processor (486), a peripheral system (420), a user interface system (430), and a data storage system (440). The peripheral system (420), the user interface system (430 and the data storage system (440) are communicatively connected to the processor (486). Processor (486) can be communicatively connected to network (450) (shown in phantom), e.g., the Internet or a leased line, as discussed below. Processor (486), and other processing devices described herein, can each include one or more microprocessors, microcontrollers, field-programmable gate arrays (FPGAs), application-specific integrated circuits (ASICs), programmable logic devices (PLDs), programmable logic arrays (PLAs), programmable array logic devices (PALs), or digital signal processors (DSPs).

Processor (486) can implement processes of various aspects described herein. Processor (486) can be or include one or more device(s) for automatically operating on data, e.g., a central processing unit (CPU), microcontroller (MCU), desktop computer, laptop computer, mainframe computer, personal digital assistant, digital camera, cellular phone, smartphone, or any other device for processing data, managing data, or handling data, whether implemented with electrical, magnetic, optical, biological components, or otherwise. Processor (486) can include Harvard-architecture components, modified-Harvard-architecture components, or Von-Neumann-architecture components.

The phrase “communicatively connected” includes any type of connection, wired or wireless, for communicating data between devices or processors. These devices or processors can be located in physical proximity or not. For example, subsystems such as peripheral system (420), user interface system (430), and data storage system (440) are shown separately from the data processing system (486) but can be stored completely or partially within the data processing system (486).

The peripheral system (420) can include one or more devices configured to provide digital content records to the processor (486). For example, the peripheral system (420) can include digital still cameras, digital video cameras, cellular phones, or other data processors. The processor (486), upon receipt of digital content records from a device in the peripheral system (420), can store such digital content records in the data storage system (440).

The user interface system (430) can include a mouse, a keyboard, another computer (connected, e.g., via a network or a null-modem cable), or any device or combination of devices from which data is input to the processor (486). The user interface system (430) also can include a display device, a processor-accessible memory, or any device or combination of devices to which data is output by the processor (486). The user interface system (430) and the data storage system (440) can share a processor-accessible memory.

In various aspects, processor (486) includes or is connected to communication interface (415) that is coupled via network link (416) (shown in phantom) to network (450). For example, communication interface (415) can include an integrated services digital network (ISDN) terminal adapter or a modem to communicate data via a telephone line; a network interface to communicate data via a local-area network (LAN), e.g., an Ethernet LAN, or wide-area network (WAN); or a radio to communicate data via a wireless link, e.g., WiFi or GSM. Communication interface (415) sends and receives electrical, electromagnetic or optical signals that carry digital or analog data streams representing various types of information across network link (416) to network (450). Network link (416) can be connected to network (450) via a switch, gateway, hub, router, or other networking device.

Processor (486) can send messages and receive data, including program code, through network (450), network link (416) and communication interface (415). For example, a server can store requested code for an application program (e.g., a JAVA applet) on a tangible non-volatile computer-readable storage medium to which it is connected. The server can retrieve the code from the medium and transmit it through network (450) to communication interface (415). The received code can be executed by processor (486) as it is received or stored in data storage system (440) for later execution.

Data storage system (440) can include or be communicatively connected with one or more processor-accessible memories configured to store information. The memories can be, e.g., within a chassis or as parts of a distributed system. The phrase “processor-accessible memory” is intended to include any data storage device to or from which processor (486 can transfer data (using appropriate components of peripheral system (420), whether volatile or nonvolatile; removable or fixed; electronic, magnetic, optical, chemical, mechanical, or otherwise. Exemplary processor-accessible memories include but are not limited to registers, floppy disks, hard disks, tapes, bar codes, Compact Discs, DVDs, read-only memories (ROM), erasable programmable read-only memories (EPROM, EEPROM, or Flash), and random-access memories (RAMs). One of the processor-accessible memories in the data storage system (440) can be a tangible non-transitory computer-readable storage medium, i.e., a non-transitory device or article of manufacture that participates in storing instructions that can be provided to processor (486) for execution.

In an example, data storage system (440) includes code memory (441), e.g., a RAM, and disk (443), e.g., a tangible computer-readable rotational storage device such as a hard drive. Computer program instructions are read into code memory (441) from disk (443). Processor (486) then executes one or more sequences of the computer program instructions loaded into code memory (441), as a result performing process steps described herein. In this way, processor (486) carries out a computer implemented process. For example, steps of methods described herein, blocks of the flowchart illustrations or block diagrams herein, and combinations of those, can be implemented by computer program instructions. Code memory (441) can also store data or can store only code.

Various aspects described herein may be embodied as systems or methods. Accordingly, various aspects herein may take the form of an entirely hardware aspect, an entirely software aspect (including firmware, resident software, micro-code, etc.), or an aspect combining software and hardware aspects These aspects can all generally be referred to herein as a “service,” “circuit,” “circuitry,” “module,” or “system.”

Furthermore, various aspects herein may be embodied as computer program products including computer readable program code stored on a tangible non-transitory computer readable medium. Such a medium can be manufactured as is conventional for such articles, e.g., by pressing a CD-ROM. The program code includes computer program instructions that can be loaded into processor (486 (and possibly also other processors), to cause functions, acts, or operational steps of various aspects herein to be performed by the processor (486) (or other processor). Computer program code for carrying out operations for various aspects described herein may be written in any combination of one or more programming language(s) and can be loaded from disk (443) into code memory (441) for execution. The program code may execute, e.g., entirely on processor (486) partly on processor (486) and partly on a remote computer connected to network (450), or entirely on the remote computer.

While examples, one or more representative embodiments and specific forms of the disclosure have been illustrated and described in detail in the drawings and foregoing description, the same is to be considered as illustrative and not restrictive or limiting. The description of particular features in one embodiment does not imply that those particular features are necessarily limited to that one embodiment. Some or all of the features of one embodiment can be used in combination with some or all of the features of other embodiments as would be understood by one of ordinary skill in the art, whether or not explicitly described as such. One or more exemplary embodiments have been shown and described, and all changes and modifications that come within the spirit of the disclosure are desired to be protected.

I/We claim:

1. A method of generating a computational model representative of a bridge, comprising:
a) receiving a first user input representative of a bridge, wherein the first user input includes a bridge type selection from a plurality of stored bridge types, wherein each of the plurality of stored bridge types correlates to a plurality of bridge parameters;
b) receiving a second user input representative of the bridge, wherein the second user input includes a plurality of bridge parameters correlating to the first user input;
c) generating a three-dimensional (3D) bridge model based upon the second user input;
d) generating a computation fluid dynamics (CFD) model representative of an area surrounding the bridge; and
e) performing a CFD analysis on the CFD model and generating output results therefrom.

2. The method of claim 1, wherein generating a computation fluid dynamics (CFD) model representative of an area surrounding the bridge includes:
a) generating a mesh model;
b) merging the 3D bridge model with the mesh model;
c) refining the mesh model; and
d) defining a plurality of boundary planes of the mesh model.

3. The method of claim 2, wherein the mesh model includes a hexahedral mesh model.

4. The method of claim 2, wherein the plurality of boundary planes include symmetry planes and ground planes.

5. The method of claim 1, wherein the CFD analysis on the mesh model includes one or more wind data inputs.

6. The method of claim 1, wherein generating a three-dimensional (3D) bridge model includes operating a computer-aided design software package.

7. The method of claim 1, wherein generating a three-dimensional (3D) bridge model includes operating a photogrammetry software package.

8. The method of claim 1, further comprising converting the output results to an FBX file format.

9. A method of deploying an aerial vehicle system to inspect a structure, comprising:
a) receiving a first user input representative of a structure, wherein the first user input includes a structure type selection from a plurality of stored structure types, wherein each of the plurality of stored structure types correlates to a plurality of structure parameters;
b) receiving a second user input representative of the structure, wherein the second user input includes a plurality of structure parameters corresponding to the first user input;
c) generating a three-dimensional (3D) structure model based upon the second user input;
d) generating a computation fluid dynamics (CFD) model representative of an area around the structure;
e) performing a CFD analysis on the CFD model and generating output results therefrom; and
f) transmitting the output results to an aerial vehicle system.

10. The method of claim 9, wherein the aerial vehicle system includes an unmanned aircraft.

11. The method of claim 9, wherein transmitting the output results to the aerial vehicle system includes transmitting the output results to the aerial vehicle system in regular intervals during flight.

12. The method of claim 9, comprising displaying a visual representation of the output results to a remote user display in regular intervals during flight of the aerial vehicle system.

13. The method of claim 9, wherein generating the computation fluid dynamics (CFD) model representative of the area around the structure includes:
a) generating a mesh model;
b) merging the 3D bridge model with the mesh model;
c) refining the mesh model; and
d) defining a plurality of boundary planes of the mesh model.

14. The method of claim 13, wherein the mesh model includes a hexahedral mesh model.

15. The method of claim 13, wherein the plurality of boundary planes include symmetry planes and ground planes.

16. The method of claim 9, wherein the CFD analysis on the mesh model includes one or more wind data inputs.

17. The method of claim 9, wherein generating a three-dimensional (3D) structure model includes operating a computer-aided design software package.

18. The method of claim 9, wherein generating a three-dimensional (3D) structure model includes operating a photogrammetry software package.

19. The method of claim 9, comprising:
upon generating output results, converting the output results to an FBX file format.

20. A method of deploying an aerial vehicle system to inspect a structure, comprising:
a) receiving a first user input representative of a structure, wherein the first user input includes a structure type selection from a plurality of stored structure types, wherein each of the plurality of stored structure types correlates to a plurality of structure parameters;
b) receiving a second user input representative of the structure, wherein the second user input includes a plurality of structure parameters corresponding to the first user input;
c) generating a three-dimensional (3D) structure model based upon the second user input;
d) generating a computation fluid dynamics (CFD) model representative of an area around the structure, wherein the CDF model includes one or more wind data sets;
e) performing a CFD analysis on the CFD model and generating output results therefrom, wherein the output results include a wind data profile around the structure; and
f) displaying the output results to a user display, wherein the user display is selectively manipulable by the user to view the wind data profile.
